(19) United States
(12) Patent Application Publication
(10) Pub. No.: US 2010/0248474 A1
(43) Pub. Date: Sep. 30, 2010

(54) METHOD OF FORMING COATING-TYPE FILM

(75) Inventor: Katsuhiro SATO, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/730,638

(22) Filed: Mar. 24, 2010

(30) Foreign Application Priority Data
Mar. 24, 2009 (JP) P2009-072336

(51) Int. Cl. H01L 21/3205; B05D 3/04; B05D 3/00; B05D 3/02; B05D 3/12; B05D 5/00

(52) U.S. Cl. 438/660; 427/337; 427/353; 427/380; 427/240; 427/256; 257/E21.295

(57) ABSTRACT

An aspect of the present invention, there is provided a method for providing a coating-type film, including, coating a solution including an organic metal compound on a surface of a substrate including a semiconductor substrate to form a coating film, heating the coating film to volatize a solvent in the coating film, and performing a treatment including at least one of a heat treatment, an ozone treatment and a moisture treatment to remove impurities from the coating film.

### CROSS REFERENCE TO RELATED APPLICATION

This application is based upon and claims the benefit of priority from prior Japanese Patent Application No. 2009-72336, filed on Mar. 24, 2009, the entire contents of which are incorporated herein by reference.

### TECHNICAL FIELD

Exemplary embodiments described herein relate to a method of forming a coating-type film, especially the method of forming a low resistive film and/or an insulator in forming an electrode and/or a wiring of electron devices.

### BACKGROUND

Generally, an electrode film, a wiring pattern or an element isolation film of electron devices has been formed by performing photolithography and etching with respect to a film formed by vacuum deposition techniques such as vacuum evaporation, sputtering, chemical vapor deposition (CVD) or the like.

However, a cost in forming the film by deposition techniques is increased due to a lower through put and an upper price of a deposition apparatus. Therefore, it is effective to form a film by coating using a coating-type material as a lower cost method instead of vacuum deposition techniques.

Spin coating, die coating, spray coating, printing coating or the like are used as coating technique and either technique has a higher through put and a lower cost apparatus as compared to vacuum deposition techniques.

Especially, printing can be directly achieve patterns by using a printing block formed desired patterns. Accordingly, printing further can obtain a lower cost by omitting forming patterns after forming a coated-type film.

In such a manner, coating has an advantage which can form a conductive film or an insulator by a lower cost. However, characteristics of the film by coating are significantly dependent to a sintering condition with heating a coated material which is different from a film formed of vacuum deposition techniques by depositing atoms or molecules.

The material forming the film is dispersed in a solvent of the coating material, as a result, includes organic components originated from the solvent.

The organic components cannot be completely removed in merely sintering with heating the coating film. Consequently, including the organic components cause faults such as rising a resistance of an electrode and a wiring or generating a leakage current on an insulator.

As a related technology, removing components originated from OH-group included in a coated polysilazane film by thermal annealing in JP-A 2005-116706 (Kokai). Furthermore, a removing method on residual organic components by ozone-included water is disclosed in JP-A 2007-201070 (Kokai).

As mentioned above, the coating film using coating methods represented by spin coating or screen printing is inferior to the film formed by vacuum deposition techniques such as vacuum evaporation or sputtering.

### SUMMARY

An aspect of the present invention, there is provided a method for providing a coating-type film, including, coating a solution including an organic metal compound on a surface of a substrate including a semiconductor substrate to form a coating film, heating the coating film to volatize a solvent in the coating film, and performing a treatment including at least one of a heat treatment, an ozone treatment and a moisture treatment to remove impurities from the coating film.

An aspect of the present invention, there is provided a method for providing a coating-type film, including, coating a solution including metal particles on a surface of a substrate including a semiconductor substrate to form a coating film, heating the coating film to volatize a solvent in the coating film, and performing a treatment including at least one of a heat treatment, an ozone treatment and a moisture treatment to remove impurities from the coating film.

### BRIEF DESCRIPTION OF THE DRAWINGS

FIG. 1 is a cross-sectional schematic view showing a method for forming a coated-type film according to a first embodiment of the present invention;

FIG. 2 is an IR spectrum of polysilazane perhydride showing as an example after heating according to the first embodiment;

FIG. 3A is a bar chart showing removing impurities in polysilazane perhydride by various kinds of treatments at room temperature and FIG. 3B is a bar chart showing removing impurities in polysilazane perhydride by various kinds of treatments at a high temperature according to the first embodiment;

FIG. 4 is a cross-sectional schematic view showing a method for forming a coated-type film according to a second embodiment of the present invention;

FIG. 5A is a bar chart showing removing impurities in a copper paste by various kinds of treatments at room temperature and FIG. 5B is a bar chart showing removing impurities in the copper paste by various kinds of treatments at a high temperature according to the second embodiment;

FIG. 6 is a cross-sectional schematic view showing a method for forming a coated-type film according to a third embodiment of the present invention;

FIG. 7A is a bar chart showing removing impurities in a silver paste by various kinds of treatments at room temperature and FIG. 7B is a bar chart showing removing impurities in the silver paste by various kinds of treatments at a high temperature according to the third embodiment.

### DETAILED DESCRIPTION

Embodiments of the present invention will be described below in detail with reference to the attached drawings. It should be noted that the present invention is not restricted to the embodiments but covers their equivalents. Throughout the attached drawings, similar or same reference numerals show similar, equivalent or same components.

### First Embodiment

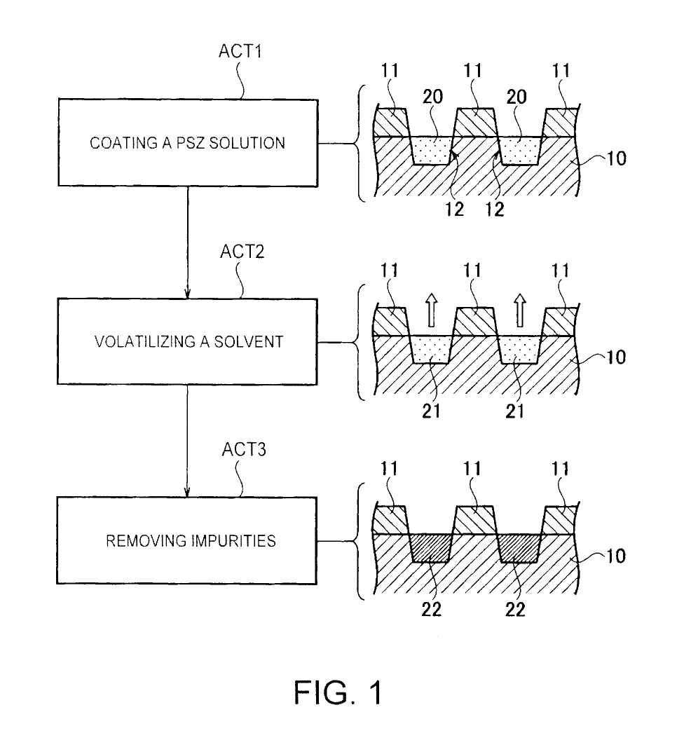

A method for forming a coated-type film according to a first embodiment of the present invention will be described below in detail with reference to FIGS. 1-3.

As shown in FIG. 1, the method for forming the coating-type film in the first embodiment includes coating ACT11, volatilizing ACT12 and removing impurities ACT13.

In coating a solution ACT11, the solution includes silazane perhydride polymer ((SiH₂ NH)ₙ) which is described as a silazane perhydride solution 20, hereafter, is coated on a silicon substrate 10 by spin coating. As a specific example, a plurality of elements 11 are formed on the silicon substrate 10, for example and a concave portion 12 is formed between adjacent elements 11. The silazane perhydride solution 20 is coated as an insulator in the concave portion 12. The silicon substrate 10 is one example as a semiconductor substrate and the silazane perhydride solution 20 is one example as a solution including an organic metal compound.

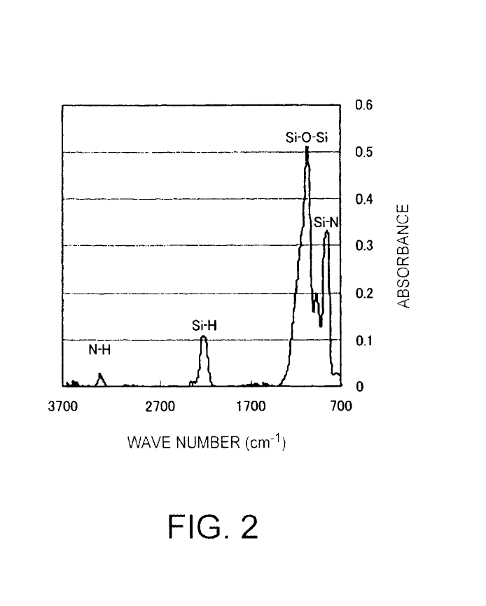

In volatilizing a solvent ACT12, the silazane perhydride solution 20 is performed to be baked at 150° C. for 3 minutes to volatilize the solvent, so that a polysilazane perhydride film 21, which is described as a PSZ film, hereafter, is formed. Next, the PSZ film 21 is performed to be oxidized at a temperature higher than 200° C. and lower than 600° C., for example, 300° C., in a steam atmosphere for 30 minutes as a first oxidation. The PSZ film 21 is partially transformed into a silicon dioxide film by the oxidation. Here, it is noted the PSZ film 21 is not a complete SiO2 film as demonstrated in an IR spectrum of FIG. 2. Further, the PSZ film 21 is analyzed by X-ray photoelectron spectroscopy (XPS) to be revealed on containing impurities nearly 36%.

In removing impurities ACT13, treatments (1)-(6) as mentioned below are performed. In the process, the PSZ film 21 is modified more stoichiometric silicon dioxide film 22 and the impurities in the PSZ film 21 are also removed.

(1) Treatment Using Ozone Gas without Heating Substrate

The substrate to be coated the PSZ film 21 is exposed in an ozone gas atmosphere for 15 minutes.

(2) Treatment using Super Heated Steam without Heating Substrate

The substrate to be coated the PSZ film 21 is exposed in a super heated steam atmosphere for 15 minutes.

(3) Treatment using Ozone Gas and Super Heated Steam without Heating Substrate

The substrate to be coated the PSZ film 21 is exposed in a mixed atmosphere with ozone gas and super heated steam for 15 minutes.

(4) Treatment using Ozone Gas with Heating Substrate The substrate to be coated the PSZ film 21 is exposed in an ozone gas atmosphere at 250° C. for 15 minutes.

(5) Treatment Using Super Heated Steam with Heating Substrate

The substrate to be coated the PSZ film 21 is exposed in a super heated steam atmosphere at 250° C. for 15 minutes.

(6) Treatment Using Ozone Gas and Super Heated Steam with Heating Substrate

The substrate to be coated the PSZ film 21 is exposed in a mixed atmosphere with ozone gas and super heated steam at 250° C. for 15 minutes.

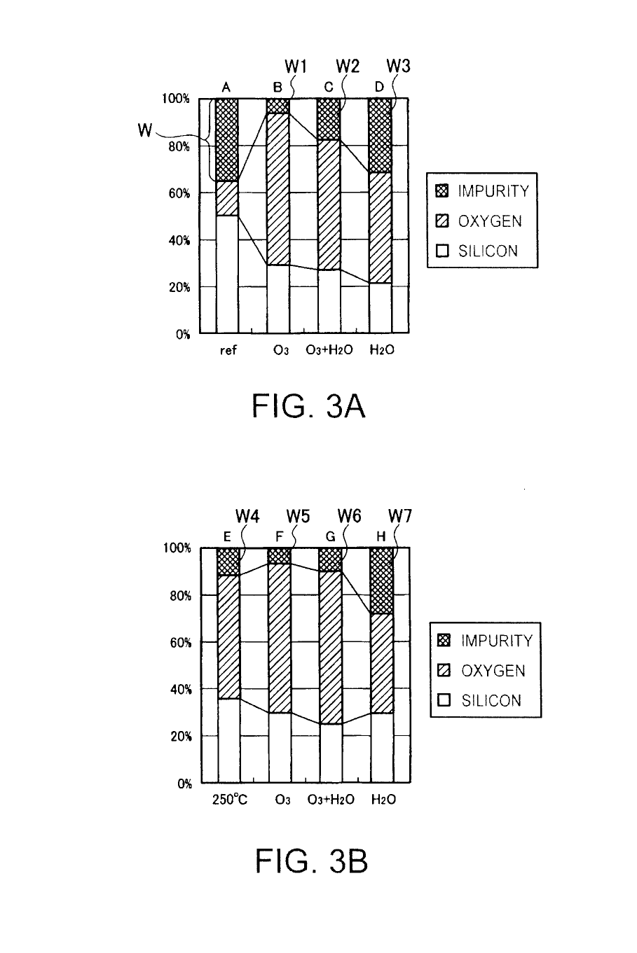

FIGS. 3A and 3B show composition ratios in the PSZ films. FIGS. 3A shows removing impurities in polysilazane perhydride by various treatments in room temperature. FIGS. 3B shows removing impurities in polysilazane perhydride by various treatments in a high temperature.

FIG. 3A shows removing impurities in the room temperature. Reference A, a treatment B by ozone gas, a treatment C by the mixed gas with ozone gas and super heated steam, and a treatment D by super heated steam are demonstrated in FIG. 3A. The reference A before removing the impurities is demonstrated as an incomplete state of the PSZ film as shown in FIG. 2 to and to include 36% of impurities W.

In FIG. 3A, impurities W1 in the treatment B by ozone gas, impurities W2 in the treatment C by ozone gas and super heated steam, and impurities W3 in the treatment D by super heated steam are less than the impurities W in the reference A. The impurities W1 are decreased to 5% at maximum.

FIG. 3B shows removing the impurities at a higher temperature. A treatment E at 50° C., a treatment F by ozone gas, a treatment G by ozone gas and super heated steam, and a treatment H by super heated steam are demonstrated in FIG. 3B.

In FIG. 3B, impurities W4 in the treatment E at 50° C., impurities W5 in the treatment F by ozone gas, impurities W6 in the treatment G by ozone gas and super heated steam, and impurities W7 in the treatment H by super heated steam are less than the impurities W in the reference A as shown in FIG. 3A.

The method for forming the coating-type film in the first embodiment mentioned above includes coating the solution at least including an organic metal compound on substrate including the semiconductor substrate, volatilizing the solvent by thermally annealing the coating film, and removing impurities by treating with at least one of thermal annealing, the ozone treatment and the steam treatment. In volatilizing, the solvent in the coating-type film can be volatilized and/or the coating-type film is can be modified.

The solution includes at least one of elements in copper, silver, indium, tin, zinc and silicon, and oxides of the elements. As another case, the solution includes at least one of elements in copper, silver, indium, tin, zinc and silicon, and organic compounds of the elements.

### Second Embodiment

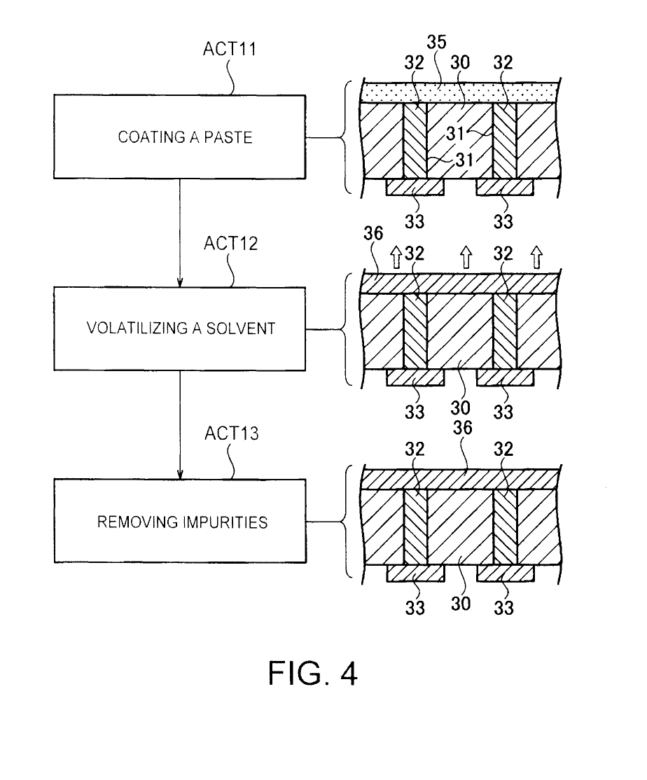

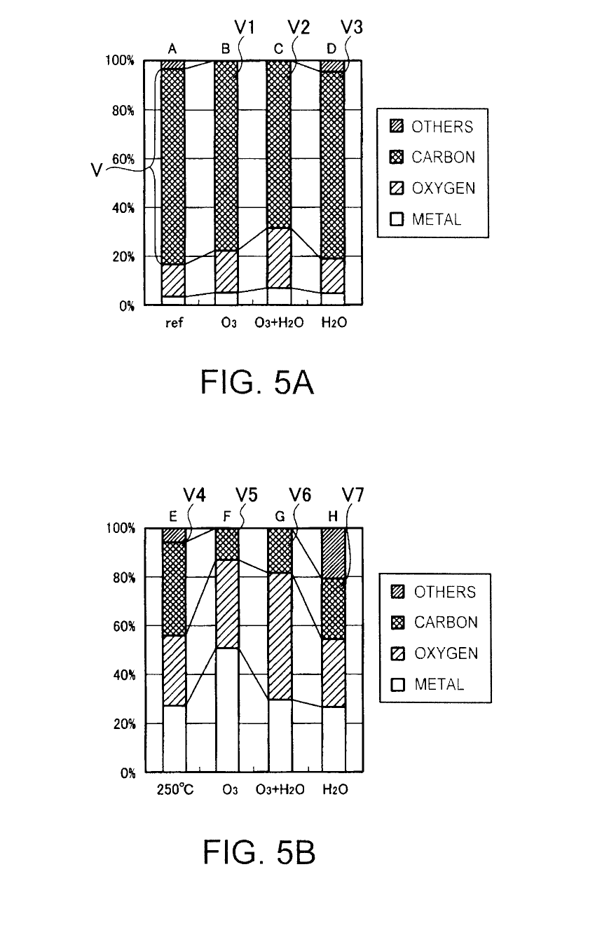

A method for forming a coated-type film according to a second embodiment of the present invention will be described below in detail with reference to FIGS. 4-5.

As shown in FIG. 4, the method for forming the coating-type film in the second embodiment includes coating AST21, volatilizing ACT22 and removing impurities ACT23.

In coating ACT11, a paste including Cu (product of DAIKEN CHEMISTRY CO., LTD.) is coating on the silicon substrate by screen printing. As a specific example, a through hole 31 is formed in a silicon substrate 30, and a conductive film 32 is formed in the through hole 31 to electrically connect to an element 33. A paste 35 including Cu is coated on the silicon substrate 30 to electrically connect to conductive film.

In volatilizing a solvent ACT12, the paste 35 is performed to be baked at 150° C. for 3 minutes to volatilize the solvent, so that Cu conductive film 36 is formed.

In removing impurities ACT13, treatments (1)-(6) as mentioned below are performed. In the process, the impurities are removed from the Cu conductive film 36.

(1) Treatment using Ozone Gas without Heating Substrate

The substrate to be coated the Cu conductive film 36 is exposed in an ozone gas atmosphere for 15 minutes.

(2) Treatment using Super Heated Steam without Heating Substrate

The substrate to be coated the Cu conductive film 36 is exposed in a super heated steam atmosphere for 15 minutes.

(3) Treatment using Ozone Gas and Super Heated Steam without Heating Substrate

The substrate to be coated the Cu conductive film 36 is exposed in a mixed atmosphere with ozone gas and super heated steam for 15 minutes.

(4) Treatment Using Ozone Gas with Heating Substrate

The substrate to be coated the Cu conductive film 36 is exposed in an ozone gas atmosphere at 250° C. for 15 minutes.

(5) Treatment Using Super Heated Steam with Heating Substrate

The substrate to be coated the Cu conductive film 36 is exposed in a super heated steam atmosphere at 250° C. for 15 minutes.

(6) Treatment Using Ozone Gas and Super Heated Steam with Heating Substrate

The substrate to be coated the Cu conductive film 36 is exposed in a mixed atmosphere with ozone gas and super heated steam at 250° C. for 15 minutes.

FIGS. 5A and 5B show composition ratios in the Cu conductive films. FIGS. 5A shows removing impurities in the Cu paste by various treatments in room temperature. FIGS. 5B shows removing impurities in the Cu paste by various treatments in a high temperature. In this case, the impurities V are carbon.

FIG. 5A shows removing impurities in the room temperature. Reference A, a treatment B by ozone gas, a treatment C by the mixed gas with ozone gas and super heated steam, and a treatment D by super heated steam are demonstrated in FIG. 5A. The reference A includes 81% of impurities V.

In FIG. 5A, impurities V1 in the treatment B by ozone gas, impurities V2 in the treatment C by ozone gas and super heated steam, and impurities V3 in the treatment D by super heated steam are less than the impurities V in the reference A. The impurities V5 are decreased to 13.4% at maximum.

FIG. 5B shows removing the impurities at a higher temperature. A treatment E at 250° C., a treatment F by ozone gas, a treatment G by ozone gas and super heated steam, and a treatment H by super heated steam are demonstrated in FIG. 5B.

In FIG. 5B, impurities W4 in the treatment E at 250° C., impurities V5 in the treatment F by ozone gas, impurities V6 in the treatment G by ozone gas and super heated steam, and impurities V7 in the treatment H by super heated steam are fairly less than the impurities V in the reference A as shown in FIG. 5A.

The method for forming the coating-type film in the second embodiment mentioned above includes coating the solution at least including metal fine particles on substrate including the semiconductor substrate, volatilizing the solvent by thermally annealing the coating film, and removing impurities by treating with at least one of thermal annealing, the ozone treatment and the steam treatment. In volatilizing, the solvent in the coating-type film is volatilized and/or the coating-type film is modified.

The solution includes at least one of elements in copper, silver, indium, tin, zinc and silicon, and oxides of the element. As another case, the solution includes at least one of elements in copper, silver, indium, tin, zinc and silicon, and organic compounds of the element.

### Third Embodiment

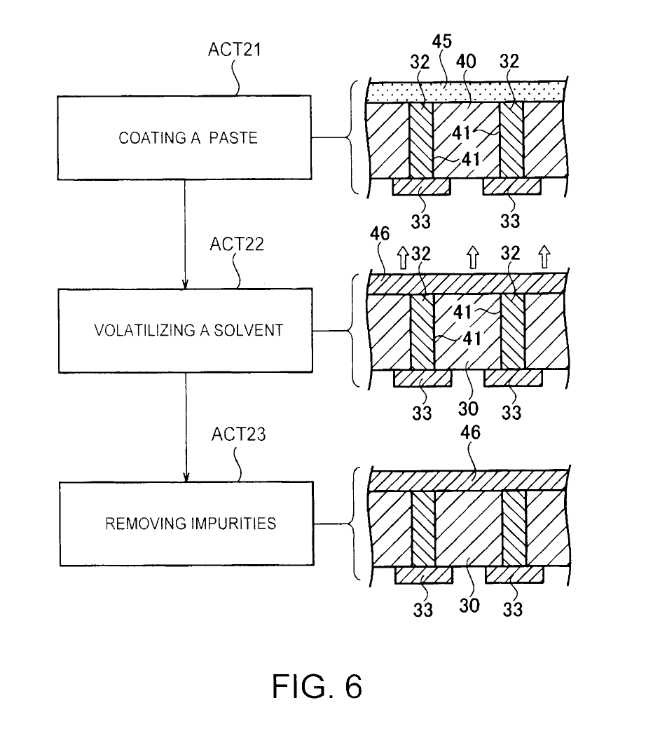

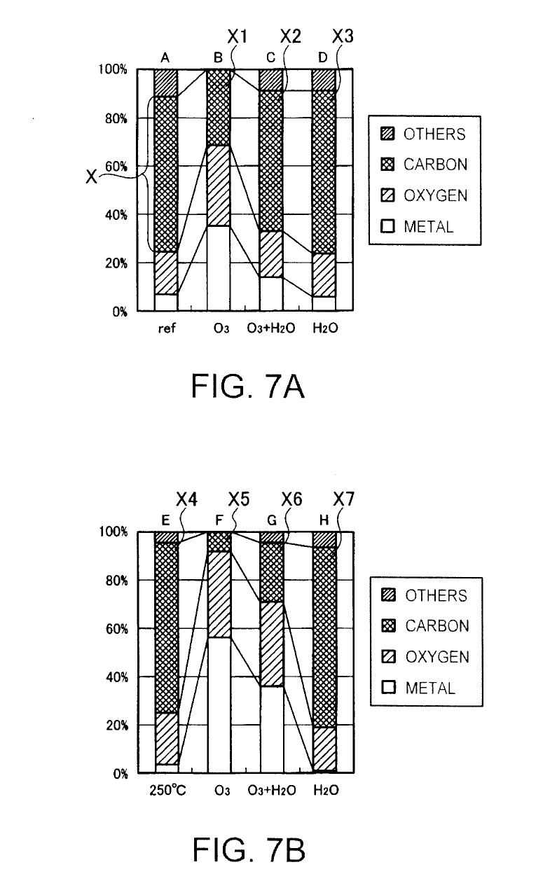

A method for forming a coated-type film according to a third embodiment of the present invention will be described below in detail with reference to FIGS. 6-7.

As shown in FIG. 6, the method for forming the coating-type film in the third embodiment includes coating ACT21, volatilizing ACT22 and removing impurities ACT23.

In coating ACT21, a paste including Ag (product of DAIKEN CHEMISTRY CO., LTD.) is coating on the silicon substrate by screen printing. As a specific example, a through hole 31 is formed in a silicon substrate 30, and a conductive film 32 is formed in the through hole 31 to electrically connect to an element 33. A paste 45 including Ag is coated on the silicon substrate 30 to electrically connect to conductive film.

In volatilizing a solvent ACT22, the paste 35 is performed to be baked at 150° C. for 3 minutes to volatilize the solvent, so that Ag conductive film 46 is formed.

In removing impurities ACT23, treatments (1)-(6) as mentioned below are performed. In the process, the impurities are removed from the Ag conductive film 46.

(1) Treatment Using Ozone Gas without Heating Substrate

The substrate to be coated the Ag conductive film 46 is exposed in an ozone gas atmosphere for 15 minutes.

(2) Treatment Using Super Heated Steam without Heating

### Substrate

The substrate to be coated the Ag conductive film 46 is exposed in a super heated steam atmosphere for 15 minutes.

(3) Treatment using Ozone Gas and Super Heated Steam without Heating Substrate

The substrate to be coated the Ag conductive film 46 is exposed in a mixed atmosphere with ozone gas and super heated steam for 15 minutes.

(4) Treatment Using Ozone Gas with Heating Substrate

The substrate to be coated the Ag conductive film 46 is exposed in an ozone gas atmosphere at 250° C. for 15 minutes.

(5) Treatment Using Super Heated Steam with Heating Substrate

The substrate to be coated the Ag conductive film 46 is exposed in a super heated steam atmosphere at 250° C. for 15 minutes.

(6) Treatment Using Ozone Gas and Super Heated Steam with Heating Substrate

The substrate to be coated the Ag conductive film 46 is exposed in a mixed atmosphere with ozone gas and super heated steam at 250° C. for 15 minutes.

FIGS. 7A and 7B show composition ratios in the Ag conductive films. FIGS. 7A shows removing impurities in the Ag paste by various treatments in room temperature. FIGS. 7B shows removing impurities in the Ag paste by various treatments in a high temperature. In this case, the impurities X are carbon.

FIG. 7A shows removing impurities in the room temperature. Reference A, a treatment B by ozone gas, a treatment C by the mixed gas with ozone gas and super heated steam, and a treatment D by super heated steam are demonstrated in FIG. 5A. The reference A includes 65% of impurities X.

In FIG. 7A, impurities X1 in the treatment B by ozone gas, impurities X2 in the treatment C by ozone gas and super heated steam, and impurities X3 in the treatment D by super heated steam are less than the impurities X in the reference A. The impurities X5 are decreased to 7% at maximum.

FIG. 7B shows removing the impurities at a higher temperature. A treatment E at 250° C., a treatment F by ozone gas, a treatment G by ozone gas and super heated steam, and a treatment H by super heated steam are demonstrated in FIG. 7B.

In FIG. 7B, impurities X4 in the treatment E at 250° C., impurities X5 in the treatment F by ozone gas, impurities X6 in the treatment G by ozone gas and super heated steam, and impurities X7 in the treatment H by super heated steam are less than the impurities X in the reference A as shown in FIG. 7A.

The method for forming the coating-type film in the third embodiment mentioned above includes coating the solution at least including metal fine particles on substrate including the semiconductor substrate, volatilizing the solvent by thermally annealing the coating film, and removing impurities by treating with at least one of thermal annealing, the ozone treatment and the steam treatment. In volatilizing, the solvent in the coating-type film is volatilized and/or the coating-type film is modified.

The solution includes at least one of elements in copper, silver, indium, tin, zinc and silicon, and oxides of the element. As another case, the solution includes at least one of elements in copper, silver, indium, tin, zinc and silicon, and organic compounds of the element.

In each embodiment mentioned above, coating is a process in which a coating solution can be coated by using one of spin coating, anastatic printing coating, hole printing coating, planar printing coating, intaglio printing coating, and ink-jet coating.

In volatilizing, a sample is thermally annealed in a range of 50° C.-300° C. Removing a solvent is insufficient when the thermal annealing temperature is below 50° C. and the silicon substrate may be damaged when the thermal annealing temperature is above 300° C. Accordingly, the two case mentioned above are undesirable.

In removing impurities, a sample is thermally annealed in a range of 25° C.-400° C. An apparatus is necessary when the thermal annealing temperature is below 25° C., and the silicon substrate may be damaged when the thermal annealing temperature is above 400° C. Accordingly, the two case mentioned above are undesirable.

The method for forming the coating-type film in the present invention includes coating the solution at least including an organic metal compound on substrate including the semiconductor substrate, volatilizing the solvent by thermally annealing the coating film, and removing impurities by treating with at least one of thermal annealing, the ozone treatment and the steam treatment.

In this manner, organic components originated from coating film in a solvent can be removed when using coating technique. Consequently, processing steps with lower cost such as printing, coating or the like can be applied to form a low resistance film or an insulator in fabricating for an electron device with an electrode and/or a wiring.

Further, the method for forming the coating-type film in the present invention includes coating the solution at least including metal fine particles on substrate including the semiconductor substrate, volatilizing the solvent by thermally annealing the coating film, and removing impurities by treating with at least one of thermal annealing, the ozone treatment and the steam treatment.

In this manner, organic components originated from coating film in a solvent can be removed when using coating technique. Consequently, processing steps with lower cost such as printing, coating or the like can be applied to form a low resistance film or an insulator in fabricating for an electron device with an electrode and/or a wiring.

Other embodiments of the present disclosure will be apparent to those skilled in the art from consideration of the specification and practice of the disclosure disclosed herein. It is intended that the specification and example embodiments are considered as exemplary only, with a true scope and spirit of the disclosure being indicated by the claims that follow. The disclosure can be carried out by being variously modified within a range not deviated from the gist of the disclosure.

What is claimed is:

1. A method of providing a coating-type film, comprising;
coating a solution including an organic metal compound on a surface of a substrate including a semiconductor substrate to form a coating film;
heating the coating film to volatize a solvent in the coating film; and
performing a treatment including at least one of a heat treatment, an ozone treatment and a moisture treatment to remove impurities from the coating film.

2. The method of claim 1, wherein
the solution includes at least one of elements in copper, silver, indium, zinc and silicon, and the oxides in the elements.

3. The method of claim 1, wherein
the solution includes at least one of elements in copper, silver, indium, zinc and silicon, and the organic compound in the elements.

4. The method of claim 1, wherein
the solution in printing is coated by one of spin coating, anastatic printing coating, hole printing coating, planar printing coating, intaglio printing coating, and ink-jet coating.

5. The method of claim 1, wherein
the coating film is heated in a range from 50° C. to 300° C. in volatizing.

6. The method of claim 1, wherein
the coating film is heated in a range from 25° C. to 400° C. in removing.

7. A method of providing a coating-type film, comprising;
coating a solution including metal particles on a surface of a substrate including a semiconductor substrate to form a coating film;
heating the coating film to volatize a solvent in the coating film; and
performing a treatment including at least one of a heat treatment, an ozone treatment and a moisture treatment to remove impurities from the coating film.

8. The method of claim 7, wherein
the solution includes at least one of elements in copper, silver, indium, zinc and silicon, and the oxides in the elements.

9. The method of claim 7, wherein
the solution includes at least one of elements in copper, silver, indium, zinc and silicon, and the organic compound in the elements.

10. The method of claim 7, wherein
the coating film in printing is coated by one of spin coating, anastatic printing coating, hole printing coating, planar printing coating, intaglio printing coating, and ink-jet coating.

11. The method of claim 7 wherein
the coating film is heated in a range from 50° C. to 300° C. in volatizing.

12. The method of claim 7, wherein
the coating film is heated in a range from 25° C. to 400° C. in removing.
